(19) United States
(12) Patent Application Publication
(10) Pub. No.: US 2019/0229147 A1
(43) Pub. Date: Jul. 25, 2019

(54) IMAGE SENSOR AND METHOD OF MANUFACTURING THE SAME

(71) Applicant: STMicroelectronics (Crolles 2) SAS, Crolles (FR)

(72) Inventors: Yannick SANCHEZ, St. Nazaire Les Aymes (FR); Emilie DELOFFRE, Saint Ismier (FR)

(73) Assignee: STMicroelectronics (Crolles 2) SAS, Crolles (FR)

(21) Appl. No.: 16/251,595

(22) Filed: Jan. 18, 2019

(30) Foreign Application Priority Data
Jan. 22, 2018 (FR) 1850475

(51) Int. Cl. H01L 27/146

(52) U.S. Cl. CPC H01L 27/14687; H01L 27/14689; H01L 27/14643; H01L 27/14627; H01L 27/14632; H01L 27/14685

(57) ABSTRACT

An image sensor manufacturing method includes forming a cavity in a first plate and mounting an active layer including both image sensing components and logic components to the first plate. The active layer is pressed against the first plate in a manner such that the image sensing components in the active layer are located on walls of the cavity and the logic components in the active layer are located outside of the cavity.

### PRIORITY CLAIM

This application claims the priority benefit of French Application for Patent No. 1850475, filed on Jan. 22, 2018, the content of which is hereby incorporated by reference in its entirety to the maximum extent allowable by law.

### TECHNICAL FIELD

The present disclosure relates to an image sensor and to methods of manufacturing an image sensor.

### BACKGROUND

Image sensors are used in many devices, including smart phones and cameras, having a thickness which is desired to be decreased.

An image sensor generally comprises an active layer capable of capturing the light signals and of transmitting electric signals representative of the captured light signals, as well as an objective, formed of circular lenses which generate a curved image. When the active layer is flat, as occurs for currently available image sensors, the objective comprises a plurality of lenses, which increases the thickness of each sensor. Despite the presence of such lenses, there is a loss of image quality from the center to the edges of the images.

There is accordingly a need in the art to overcome all or part of the disadvantages of usual image sensors.

### SUMMARY

Thus, an embodiment provides a method of manufacturing image sensors where an active layer made of semiconductor material is pressed against the walls of cavities of a first plate. According to an embodiment, the method comprises steps of: a) etching cavities on a first side of a first plate; b) forming through holes in a second plate; c) attaching an active layer to a first side of the second plate; and d) placing the first side of the second plate on the first side of the first plate, so that each through hole is located opposite a cavity.

According to an embodiment, the method comprises, between steps a) and d), a step of depositing a first bonding layer on the first side of the first plate.

According to an embodiment, the method comprises, between steps b) and c), a step of depositing a second bonding layer on the first side of the second plate.

According to an embodiment, the method comprises a step e) subsequent to step d) of increasing a first pressure at which step d) is carried out, to reach a second pressure.

According to an embodiment, the second pressure is the atmospheric pressure.

According to an embodiment, the first pressure is in the range from 0.001 and 50 mbar.

According to an embodiment, the horizontal cross-section of a cavity is substantially circular. According to an embodiment, the horizontal cross-section of a cavity is substantially rectangular.

According to an embodiment, a vertical cross-section of a cavity has substantially the shape of a portion of a circle.

According to an embodiment, after step c), the active layer is thinned down to a thickness in the range from 6 to 100 μm.

Another embodiment provides an image sensor comprising a plate made of semiconductor material comprising a cavity with a vertical cross-section substantially in the shape of a portion of a circle covered with an active layer.

According to an embodiment, the sensor comprises logic components located in the semiconductor material around the cavity.

According to an embodiment, at least a portion of the active layer is located opposite a lens.

An embodiment provides an image sensor such as previously described, formed by a manufacturing method such as previously described.

### BRIEF DESCRIPTION OF THE DRAWINGS

The foregoing and other features and advantages will be discussed in detail in the following non-limiting description of specific embodiments in connection with the accompanying drawings, wherein:

FIG. 1 is a simplified cross-section view of an embodiment of curved image sensors;

FIGS. 2A to 2H are simplified cross-section and perspective views of an embodiment of a method of manufacturing a sensor such as illustrated in FIG. 1; and

FIGS. 3A to 3C illustrate an image sensor obtained by the method of FIGS. 2A to 2H in a perspective view, a cross-section view, and a top view.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed. In particular, the different connections of the sensors or of the components surrounding them are not detailed.

In the following description, when reference is made to terms qualifying position, such as terms “upper”, “lower”, etc., or terms qualifying orientation such as terms “horizontal”, “vertical”, etc., reference is made to the orientation of the concerned elements in the drawings. The terms “approximately” and “substantially” are used herein to designate a tolerance of plus or minus 10%, preferably of plus or minus 5%, of the value in question.

By using a curved sensor, which operates similarly to the human eye, it is possible to adapt to the field curvature of the used objective. This enables to use fewer lenses in the objective, for example, a single lens, and thus to obtain sensors having a smaller thickness, which are thus less expensive. This further provides a better image quality and a better resolution.

FIG. 1 is a simplified cross-section view of an embodiment of image sensors 2 having a curved shape. More specifically, FIG. 1 partially shows a plate 4 having image sensors 2 formed inside and on top of it. Three sensors 2 are shown in FIG. 1. Plate 4 comprises cavities 6, open on a first side of the plate (upper surface in FIG. 1), having a vertical cross-section (in the plane of the cross-section of FIG. 1) substantially shaped as portions of a circle. In the drawings, the curvature of the edges of cavities 6 is intentionally exaggerated and abrupt. In practice, the edges of cavities 14 are smoothed due to the manufacturing methods used. In other words, the edges of the cavity form a curve having a continuous derivative and thus do not form a sharp bend with the planar surface of the rest of the plate. A first side of plate 4, comprising the walls of cavities 6, is covered with an active layer 8. Active layer 8, for example, comprises photosensitive devices. Layer 8 is capable, for the portions located in cavities 6, of capturing the light signals and of emitting electric signals representative of the captured light signals. In particular, the portions located in cavities 6 may each comprise an array of photosensitive pixels, possibly covered with colored filters and with microlenses. Each cavity 6 and the corresponding portion of active layer 8 are located opposite a stack of optical elements 10 preferably comprising a single macro lens, located opposite at least one portion of the active layer, and possibly other elements such as optical fibers. Areas 12 of active layer 8 which are located outside of cavities 6, comprise, for example, logic components and interconnects. The manufacturing of the active layer and of the elements that it contains is performed by usual methods.

Plate 4 is for example made of a semiconductor material, for example, of silicon. The active layer is preferably made of a material having a thermal expansion coefficient close to that of the semiconductor material of the plate.

Space 14 between each active layer 8 and the corresponding stack of optical elements 10 is, for example, filled with air.

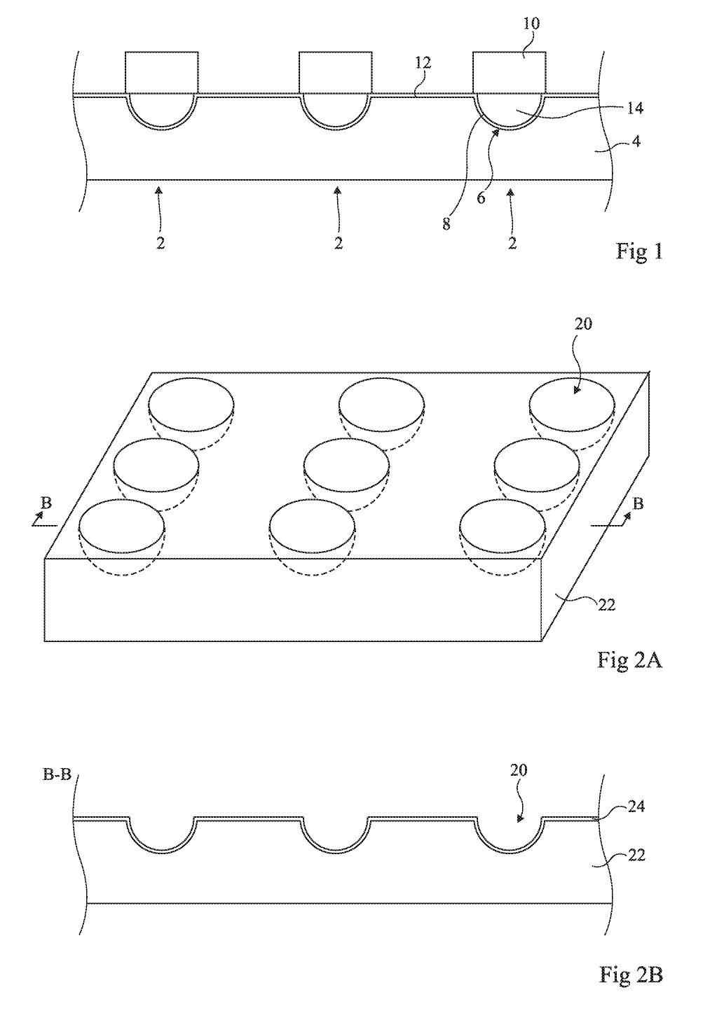

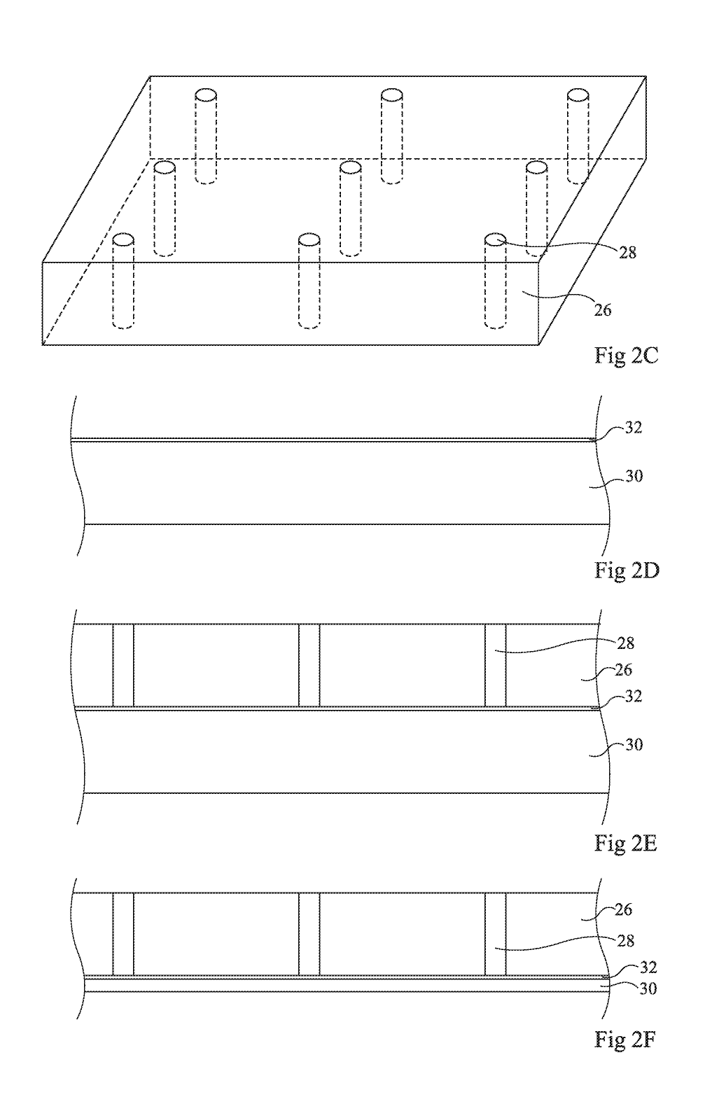

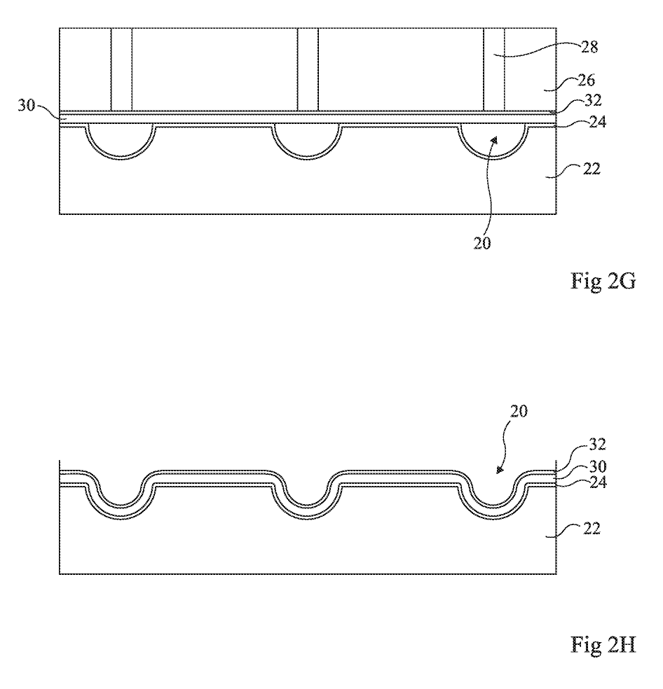

FIGS. 2A to 2H are simplified cross-section and perspective views illustrating an embodiment of a method of manufacturing a sensor such as that in FIG. 1.

The manufacturing method described in relation with FIGS. 2A to 2H is, for example, carried out in a sealed enclosure.

FIG. 2A is a simplified perspective view of a first plate 22 after a manufacturing step. During this step, cavities 20, nine of which are shown, are formed in first plate 22, and are opened on a first side of first plate 22. The first plate is, for example, made of a semiconductor material, for example, of silicon.

In the example of FIG. 2A, cavities 20 have substantially the shape of half-spheres. They thus have a horizontal cross-section, that is, in the plane of the plate, substantially circle-shaped and vertical cross-sections substantially shaped as portions of circles, for example, as a spherical cap.

More generally, cavities 20 have at least a vertical cross-section, for example, along a plane B-B, having a curved shaped, for example having substantially the shape of a portion of a circle. Further, the horizontal cross-section of each cavity 20 has any shape, preferably substantially rectangular or substantially circular.

The different cavities 20 are arranged to be connected to previously-formed components, for example, logic components, and so that it is possible to individualize the sensors formed in cavities 20. The openings of cavities 20 are inscribed within squares or rectangles having dimensions preferably in the range from 50 μm to 50 mm.

Cavities 20 are, for example, formed by using a pattern transfer etch method. For this purpose, a resist layer is spread on plate 4 and covered with a grey-scale mask and then exposed to form the desired pattern therein (this method is currently known as grey-scale lithography). The pattern in the resin layer may also be formed by a nanoimprint lithography method. Plate 4 covered with the patterned resin layer is then etched by a plasma etch method capable of transferring the initial profile of the resin layer into the material of plate 4.

FIG. 2B is a simplified cross-section view of the first plate, along plane B-B, at a subsequent manufacturing step. A bonding layer 24 is conformally formed on the first side of the first plate. Bonding layer 24 thus covers the walls of cavities 20 and the areas of the first plate, located outside of the cavities.

The bonding layer is, for example, made of a permanent adhesive resin, for example, of a siloxane-type polymer. The bonding layer, for example, has a thickness in the range from 5 μm to 75 μm.

FIG. 2C is a simplified perspective view of a second plate 26. The second plate is, for example, made of a semiconductor material, for example, silicon. Through holes 28, nine of which are shown in FIG. 2A, are formed (for example etched) in the second plate 26. The diameter of holes 28 is, for example, in the range from 50 to 200 μm. The thickness of the second plate 26 is, for example, in the range from 400 to 500 μm.

FIG. 2D is a simplified cross-section view illustrating another step of the manufacturing method. The step of FIG. 2D may be performed before or after the step of FIG. 2C.

During this step, a third plate 30 comprising the active layer, not shown, is covered, on a first side, with a bonding layer 32. The first side is the side where the active layer is formed. Third plate 30 is, for example, made of a semiconductor material. The third plate comprises, as previously discussed, a semiconductor material, for example, silicon, having the active layer formed therein. The active layer, for example, comprises an array of photosensitive pixels. Bonding layer 32 is, for example, made of a material currently used for the temporary bonding of semiconductor layers. Bonding layer 32 is, for example, made of a lightly-adhesive temporary resin, for example, of a siloxane-type polymer. The thickness of bonding layer 32 is for example in the range from 5 μm to 75 μm.

FIG. 2E is a simplified cross-section view illustrating a manufacturing step subsequent to the steps of FIGS. 2C and 2D. During this step, one of the surfaces of second plate 26 is placed in contact with bonding layer 32 of the third plate 30.

FIG. 2F is a simplified cross-section view illustrating a manufacturing step subsequent to the step of FIG. 2E. During this step, third plate 30 is thinned from its surface opposite to the active layer. The thickness of the third plate after thinning is selected so that the assembly comprising the active layer comprised in third plate 30 and bonding layer 32 can be bent without breaking. Third plate 30 has a final thickness in the range from 5 to 100 μm, preferably from 5 to 30 μm.

The steps illustrated by FIGS. 2C to 2F do not depend on the manufacturing steps illustrated in FIGS. 2A and 2B. Thus, the order of manufacturing of the first plate, on the one hand, and of the second and third plates on the other hand, may be modified.

FIG. 2G is a simplified cross-section view of a manufacturing step subsequent to steps 2A to 2F. During this step, second plate 26 is placed on first plate 22 so that third plate 30 is in contact with areas of bonding layer 24 located outside of cavities 20 (the planar portions). The contact of third plate 30 with the areas of bonding layer 24 enables to substantially tightly close cavities 20. Each hole 28 of second plate 26 is located opposite a cavity 20. Thus, plate 26 comprises at least one hole 28 per cavity 20.

The step of FIG. 2G, and possibly some of the previously-described steps, are carried out in a sealed enclosure at a first pressure. Thus, the air in cavity 20 is at the first pressure.

FIG. 2H is a simplified cross-section view of a subsequent manufacturing step. During this step, the pressure is increased up to a value enabling to separate third plate 30 and bonding layer 32 from second plate 26 and to press them into the cavity on bonding layer 24. Thus, third plate 30 and bonding layer 32 conformally cover the walls of cavity 20.

As an example, the first pressure is in the range from 0.001 to 50 mbar and the second pressure is the atmospheric pressure, that is, approximately 1,013 mbar. However, the pressure difference between the first and the second pressure is selected according to the adherence of the material of bonding layer 32. The higher the adherence of the material of the bonding layer, the greater the difference between the first and second pressures should be.

The second plate is then removed and may, for example, be used again to manufacture other sensors.

The manufacturing comprises subsequent steps, not shown, for example comprising removing bonding layer 32 and sawing the sensors to individualize them. Optical elements, preferably comprising a single lens and possibly optical filters, are assembled on each sensor vertically in line with each cavity.

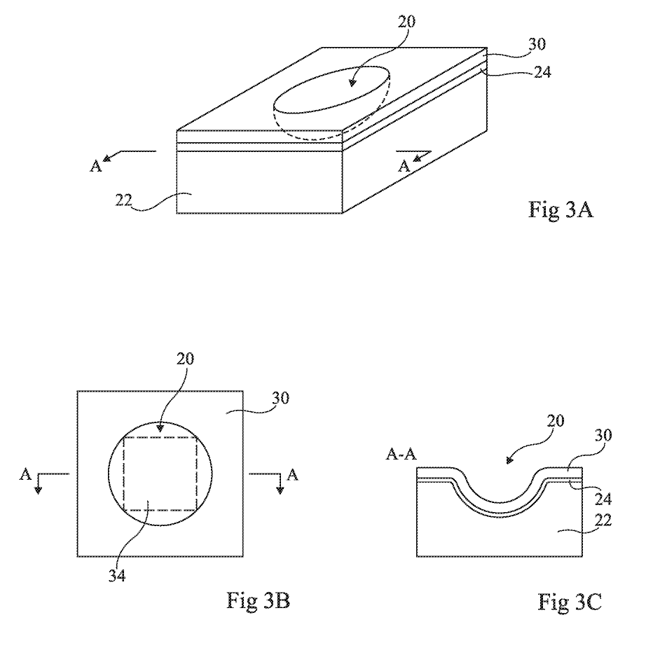

FIGS. 3A to 3C illustrate, in a perspective view (FIG. 3A), a top view (3B), and a cross-section view (FIG. 3C), an image sensor obtained by the method of FIGS. 2A to 2H. The possible optical elements formed above cavity 20 are not shown.

The illustrated sensor has been individualized, that is, cut from an assembly of sensors in a wafer obtained by the method described in relation with FIGS. 2A to 2H. The illustrated sensor may then be used in a device such as a telephone, a camera, etc.

FIGS. 3A to 3C show first plate 22, bonding layer 24, and the active layer located in third plate 30. The active layer for example comprises an array 34 of photosensitive pixels located in cavity 20. Array 34 or example has a square shape, as illustrated in FIG. 3B, or a rectangular shape. The array may also have a substantially circular shape.

As illustrated in FIG. 3C and as discussed in relation with FIG. 2A, the edges of the cavity are softened and form a curve having a continuous derivative. The edges of the cavity thus do not form an abrupt angle with the planar surface of the rest of the plate.

The various previously-formed elements, for example, the logic components and interconnects formed in the active layer, are formed by usual manufacturing methods. Similarly, the stacks of optical elements shown in FIG. 1 preferably comprising a lens are formed by usual methods.

Specific embodiments have been described. Various alterations, modifications, and improvements will occur to those skilled in the art. In particular, although FIGS. 2A to 2H illustrate the manufacturing of a plate comprising nine sensors, it should be obvious that this can be extended to the manufacturing of any number of image sensors.

Various embodiments with different variations have been described hereabove. It should be noted that those skilled in the art may combine various elements of these various embodiments and variations without showing any inventive step.

Further, the implementation of the described embodiments is within the abilities of those skilled in the art based on the functional indications given hereabove.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A method of manufacturing a plurality of image sensors, comprising pressing an active layer made of a semiconductor material against the walls of a corresponding plurality of cavities formed in a first plate.

2. The manufacturing method of claim 1, wherein pressing comprises:
extending the active layer made of the semiconductor material over the plurality of cavities;
positioning the active layer and first plate within a sealed container at a first pressure, and
increasing pressure within the sealed container from the first pressure to a second pressure which causes deformation of the active layer against walls of the plurality of cavities.

3. The manufacturing method of claim 2, wherein the second pressure is the atmospheric pressure and wherein the first pressure is in the range from 0.001 to 50 mbar.

4. The manufacturing method of claim 2, wherein a horizontal cross-section of each cavity of the plurality of cavities is substantially circular.

5. The manufacturing method of claim 2, wherein a horizontal cross-section of each cavity of the plurality of cavities is substantially rectangular.

6. The manufacturing method of claim 2, wherein a vertical cross-section of each cavity of the plurality of cavities has substantially the shape of a portion of a circle.

7. The manufacturing method of claim 2, wherein the active layer includes image sensing components and logic components, and wherein extending comprises positioning the active layer relative to the plurality of cavities such that the image sensing components are located over each cavity and the logic components located outside of each cavity.

8. The manufacturing method of claim 7, further comprising: cutting through the active layer and the first plate to form a corresponding plurality of image sensor chips, wherein each image sensor chip includes one of the cavities with image sensing components located inside of that cavity and logic components located outside of that cavity.

9. The manufacturing method of claim 8, further comprising mounting an objective over the cavity of each image sensor chip.

10. The manufacturing method of claim 1, comprising: etching the plurality of cavities on a first side of the first plate.

11. The manufacturing method of claim 1, comprising:
forming a plurality of through holes in a second plate; and
attaching the active layer on a first side of the second plate.

12. The manufacturing method of claim 11, comprising: placing the active layer which is attached to the first side of the second plate on the first side of the first plate, so that each through hole of the plurality of through holes is located opposite a corresponding cavity of the plurality of cavities.

13. The manufacturing method of claim 12, comprising: depositing a bonding layer on the first side of the first plate before the step of placing.

14. The manufacturing method of claim 13, comprising:
placing the first plate, active layer and second plate within a sealed container; and
increasing a pressure within the sealed container from a first pressure to a second pressure which causes the pressing of the active layer into the plurality of cavities.

15. The manufacturing method of claim 14, wherein the second pressure is the atmospheric pressure.

16. The manufacturing method of claim 15, wherein the first pressure is in the range from 0.001 to 50 mbar.

17. The manufacturing method of claim 1, wherein a horizontal cross-section of each cavity of the plurality of cavities is substantially circular.

18. The manufacturing method of claim 1, wherein a horizontal cross-section of each cavity of the plurality of cavities is substantially rectangular.

19. The manufacturing method of claim 1, wherein a vertical cross-section of each cavity of the plurality of cavities has substantially the shape of a portion of a circle.

20. The manufacturing method of claim 11, further comprising, after attaching the active layer on the first side of the second plate step, thinning down the active layer to a thickness in the range from 6 to 100 μm.

21. The manufacturing method of claim 1, wherein the active layer includes image sensing components located on walls of each cavity and logic components located outside of each cavity, the method further comprising cutting through the active layer and the first plate to form a corresponding plurality of image sensor chips, wherein each image sensor chip includes one of the cavities with image sensing components located inside of that cavity and logic components located outside of that cavity.

22. The manufacturing method of claim 21, further comprising mounting an objective over the cavity of each image sensor chip.

23. An image sensor, comprising:
a plate of semiconductor material comprising a cavity in a first surface, said cavity having a vertical cross-section substantially in the shape of a portion of a circle; and
an active layer which covers the first surface both inside and outside of the cavity.

24. The image sensor of claim 23, comprising image sensing components in the active layer located on walls of the cavity and logic components in the active layer located on the first surface outside of the cavity.

25. The image sensor of claim 23, further comprising a lens position opposite the image sensing components in the active layer inside of the cavity.

26. A method of manufacturing a plurality of image sensors, comprising:
forming an active layer made of a semiconductor material to include a plurality of image sensing components;
forming a first plate to include a plurality of cavities; and
pressing the active layer against the first plate such that portions of the active layer which include the image sensing components are in contact with walls of the plurality of cavities.

27. The method of manufacturing of claim 26, further comprising:
mounting the active layer to a first surface of the first plate, wherein the plurality of cavities are formed in the first surface, within a sealed container at a first pressure; and
increasing pressure within the sealed container to a second pressure greater that the first pressure so that the change in pressure deforms the active layer to press against the walls of the plurality of cavities.

28. The method of manufacturing of claim 27, further comprising cutting through the active layer and the first plate to form a corresponding plurality of image sensor chips, wherein each image sensor chip includes one of the cavities with image sensing components located inside of that cavity.

29. The method of manufacturing of claim 27, comprising:
forming a plurality of through holes in a second plate;
attaching the active layer to the second plate with the plurality of image sensing components aligned with the plurality of through holes; and
mounting the second plate to the first plate.

30. The method of manufacturing of claim 27, wherein the second pressure is the atmospheric pressure.

31. The method of manufacturing of claim 27, wherein the first pressure is in the range from 0.001 to 50 mbar.
